(19) United States
(12) Patent Application Publication
(10) Pub. No.: US 2022/0011347 A1
(43) Pub. Date: Jan. 13, 2022

(54) INSTRUMENT FOR ANALYZING AN INPUT SIGNAL

(71) Applicant: Rohde & Schwarz GmbH & Co. KG, Munich (DE)

(72) Inventors: Andrew Schaefer, Munich (DE); Andreas Maier, Munich (DE); Moritz Pfefferkorn, Munich (DE); Lisa Wolf, Munich (DE)

(73) Assignee: Rohde & Schwarz GmbH & Co. KG, Munich (DE)

(21) Appl. No.: 16/927,371

(22) Filed: Jul. 13, 2020

(51) Int. Cl. G01R 13/02; G01R 13/32; G01R 13/22

(52) U.S. Cl. CPC G01R 13/0218; G01R 13/225; G01R 13/32

(57) ABSTRACT

The present disclosure relates to an instrument for analyzing an input signal. The instrument comprises an input for receiving an input signal, a processing circuit or module for analyzing the input signal received, a display, such as a display module, for displaying information concerning the input signal analyzed, and a user input module for receiving instructions from a user. The instrument provides several functionalities, the several functionalities each being associated with at least one respective complexity. The instrument is set by the instructions of the user via the user input to analyze the input signal. The processing module evaluates a complexity of the instructions of the user.

### FIELD OF THE DISCLOSURE

The present disclosure relates generally to an instrument for analyzing an input signal.

### BACKGROUND

In the state of the art, different types of instruments are known that are used by a user for analyzing an input signal. Such instruments are also called test and/or measurement instruments due to their respective functionalities for analyzing a device under test. A typical instrument for analyzing an input signal corresponds to an oscilloscope.

Modern instruments for analyzing an input signal have several different functionalities which are not known to the user completely. This means that the user is not aware of all the different functionalities the respective instrument provides. Furthermore, the instrument may comprise complex functionalities that cannot be achieved by a user at the beginning due to less experience with the respective instrument.

Accordingly, there is a need to provide a possibility to motivate the user of the instrument to experience new functionalities of the respective instrument, for instance unknown features of the instrument.

### SUMMARY

The present disclosure provides examples of an instrument for analyzing an input signal. In an embodiment, the instrument comprises an input for receiving an input signal, a processing circuit or module for analyzing the input signal received, a display, such as a display circuit or module, for displaying information concerning the input signal analyzed, and a user input for receiving instructions from a user. The instrument provides several functionalities, wherein the several functionalities each are associated with at least one respective complexity. The instrument is set by the instructions of the user via the user input module to analyze the input signal. The processing module evaluates a complexity of the instructions of the user.

Since the instrument is enabled to determine the complexity of an input the user has made, namely the complexity of the instructions, the instrument may use the respective information gathered internally for adapting the instrument or rather providing certain functionalities to the user.

In general, the instrument corresponds to a complex instrument that comprises internal hardware circuits that are controlled via the user input, for example the respective inputs done via an user input interface or module. The instrument analyzes the input signal in a respective manner based on the inputs done, namely a certain setting of the instrument which is associated with the instructions of the user.

Generally, the display module and the processing module together provide a graphical user interface (GUI) via which the user is enabled to obtain certain information of the instrument, for instance the respective functionalities available. The user is enabled to select one of the functionalities in order to set the instrument accordingly. In other words, the user may employ a certain setting by selecting a certain functionality or rather defining a certain functionality in more detail.

The processing module that evaluates the instructions of the user, for example with regard to the functionality and the respective complexity, is enabled to evaluate any input of the user done via the user input in order to determine the respective complexity level associated with the input, namely the instructions. Therefore, the processing module is also enabled to detect the input made by the user and to evaluate the complexity level of the respective functionality that is associated with the input of the user, namely the instructions. Thus, the processing module determines whether the respective functionality activated or rather the input (instructions) associated therewith is a more complex one compared to a certain standard complexity.

Generally, the different functionalities provided by the instrument as well as their respective different settings can be grouped in different complexity levels. Hence, the instructions associated with the different functionalities/settings may also be grouped in different complexity levels.

An aspect provides that the processing module evaluates a complexity of a setting of the instrument, the setting being defined by the instructions of the user, the setting being associated with at least one of the several functionalities of the instrument. As mentioned above, the user is enabled to set the instrument for analyzing the input signal in a certain manner by performing certain inputs or rather instructing the instrument accordingly. In other words, the instructions made by the user may inter alia relate to a setting of the test instrument. The respective setting is associated with at least one of the several functionalities which means that depending on the setting/instructions, at least one of the several functionalities of the instrument is activated (in a certain manner). This functionality has an intrinsic complexity which is associated with the instructions since the instructions concern the activation of the respective functionality having the dedicated intrinsic complexity.

According to another aspect, the processing module determines an achievement of the user based on the evaluation of the complexity of the instructions. Since the instrument is enabled to determine an achievement the user has made, the user gets motivated by the instrument itself to experience the instrument in greater detail and/or to discover new functionalities of the instrument which were unknown to the user so far. In some embodiments, the instrument, for example the processing module, determines the respective achievement of the user in order to motivate the user to use the instrument more often. Put differently, the respective achievement determined offers an incentive for the user to discover more insights of the instrument. Since the user becomes aware of features of the instrument that he was not aware of before, the user might become more fascinated by the instrument such that the user spends more time with using the instrument, thereby getting more familiar with the instrument, for example trained. This means that the user is guided through the several functionalities of the instrument based on the different achievements such that the user discovers all features or rather functionalities of the instrument accordingly.

The user learns the different functionalities of the instrument in a motivating manner which can be summarized as a playful learning due to the different achievements to be reached when using the instrument.

In any case, the instrument, for example the processing module, is configured to determine an achievement of the user based on the evaluation of the complexity of the instructions, for instance the functionality (set or rather selected by the instructions) and its complexity.

In general, the respective achievement may depend on a successful interaction or rather a certain discovery of an unknown feature or rather functionality of the instrument. Thus, the respective achievement may correspond to starting a certain analysis or rather operation mode of the instrument for the first time, for instance performing a multi-domain analysis or rather using the instrument through a remote control application, for example via an Internet browser.

Moreover, the processing module may analyze the input signal with respect to the instructions of the user, thereby obtaining analysis results. As mentioned above, the instructions received may concern a certain setting of the instrument according to which the instrument analyzes the input signal received via the input. When analyzing the input signal, analysis results are obtained that can be used for further

An aspect provides that the processing module evaluates the analysis results obtained together with the complexity of the instructions of the user in order to determine an achievement of the user. The respective achievement may be reached by the user in case that the analysis results are correct. Therefore, the processing module evaluates whether the analysis results are correct ones or incorrect ones. Only if the analysis results are correct ones, a respective achievement was reached by the user. Additionally or alternatively, the evaluation of the analysis results obtained may indicate whether the respective setting done by the user was correct or not. Accordingly, the respective achievement may correspond to a successful measurement, for example with a respective setting set by the user previously. Hence, an achievement may correspond to a successful acquisition of a certain number of waveforms per time unit, for instance per second.

According to another aspect, the several functionalities at least partly define how the input signal received via the input is to be analyzed by the instrument. This means that the respective functionalities provided by the instrument do not necessarily have to be associated with the analysis of the input signal directly. In some embodiments, the instrument may comprise functionalities that are associated with the control of the instrument or rather its operation. For instance, a certain functionality may be associated with an interface for a remote control of the instrument such that the user is enabled to use the instrument through a remote Internet browser or an external device.

The complexity may be associated with a function of the instrument. The function of the instrument may relate to a function that is used for analyzing the input signal such as a domain analysis function or rather a certain setting of an analysis function that is used to analyze the input signal. For instance, a multi-domain analysis has a higher (intrinsic) complexity level compared to a single-domain analysis. In a similar manner, the acquisition of 1 million waveforms per second has also a higher complexity level compared to the acquisition of 100 waveforms per second or 1 million waveforms per hour.

Further, the complexity may be associated with an application of the instrument. The instrument may comprise several applications that provide certain functionalities of the instrument that can be used by the user in order to facilitate the control of the instrument. An application for remote control may be provided that can be used for controlling the instrument remotely. Such an application has a higher complexity level compared to an application associated with a main function of the instrument.

In other words, the several functionalities comprise functions of the instrument, operation modes of the instrument and/or applications running on the instrument. The user is enabled to select a certain function, operation mode and/or application via the user input module, thereby setting the instrument for analyzing the input signal accordingly. Depending on the selection of the user, namely its input, the processing module is enabled to evaluate the respective complexity of the setting done by the user, namely the respective complexity of the instructions, resulting in the respective setting.

Depending thereon, the processing module may be further enabled to determine an achievement that was reached by the user due to the setting done, wherein the achievement depends on the evaluation result.

Another aspect provides that the complexity is associated with a type of input done by the user, an intrinsic complexity of the respective functionality, a duration and/or a number of analysis results obtained. The intrinsic complexity typically relates to a certain operation mode, a certain function of the instrument or rather an application selected to be used. As mentioned above, a multi-domain analysis has a higher intrinsic complexity compared to a single-domain analysis. The type of input may also have an intrinsic complexity which however relates to how the instructions are done by the user, for instance by voice, by using a button, by using a remote device or rather by using a touch-sensitive display. For instance, a zoom functionality may be done by using a pinching operation on a touch-sensitive display, by using a zoom button or rather by using a rotary button for zoom level adaption. Furthermore, the acquisition of a certain number of measurement results or analysis results is more complex when the duration is shorter for acquiring the respective number. In a similar manner, it is more complex to acquire a higher number of analysis results in a fixed time period.

Therefore, the respective complexity depends on several parameters, for instance type of input done by the user, namely how the instructions are done, the intrinsic complexity, the duration and/or the number of analysis results obtained.

Furthermore, the processing module may control the display module to display the information concerning the input signal analyzed and/or an achievement determined. The user gets informed directly about information obtained by the instrument when analyzing the input signal and/or any achievement reached so that a direct interaction is provided.

The display module may have a touch-sensitive display that provides the user input module at least partly. The user is enabled to make at least some of the different inputs via the touch-sensitive display in order to set the instrument for analyzing the input signal. For instance, the user is enabled to select a certain operation mode, function or rather application via the touch-sensitive display. Furthermore, the user may set the function accordingly via the touch-sensitive display.

The instrument may provide different user accounts for using the instrument. Therefore, the same instrument may be used by different users which have different experiences with the respective instrument. Therefore, each of the users has its own user account so that the achievements of a respective user can be determined in an individual manner.

The processing module may take the respective user account activated into account when determining an achievement such that the achievement is based on the user account rather than the entire instrument. Hence, the processing module distinguishes the respective users while taking the respective user accounts into account, for example the one currently activated.

The instrument may comprise a data storage in which information concerning the individual users and/or the respective achievements of the individual users associated with the respective user accounts are stored. This ensures that several different users may use the instrument, wherein individual achievements can be reached by the respective users.

Accordingly, the instrument may correspond to a training instrument that is used to train the users in a playful way.

Another aspect provides that a previously locked functionality of the instrument is unlocked when the processing module determines that a certain achievement has been reached that enables the user to use the previously locked functionality of the instrument.

The user gets motivated to reach certain achievements since previously locked functionalities of the instrument may be unlocked when reaching a certain achievement, thereby ensuring that those functionalities can be used by the user in the future.

The previously locked functionality of the instrument may be unlocked for a pre-defined time or a pre-defined number of usages. Thus, the unlocking of the respective functionality is only temporary, thereby ensuring that the user can test the respective functionality unlocked in order to figure out whether it is worth to activate the functionality permanently or not.

The processing module together with the display module may generate a graphical user interface (GUI) that illustrates currently locked functionalities of the instrument which are enabled to be unlocked when reaching a respective achievement that enables the user to use a previously functionality of the instrument. Therefore, the user is aware of any functionality that can be unlocked by reaching a certain achievement since those functionalities are displayed. However, the currently locked functionalities may be displayed in a certain manner, for instance marked with a certain symbol indicating that the respective functionality is currently locked. For instance, the respective symbol may correspond to a key or anything else like that.

Alternatively, the locked functionalities may be displayed in a semi-transparent manner or rather in a crossed manner, thereby indicating that the respective functionality is not enabled at the moment.

In any case, the user gets motivated to reach the respective achievement in order to unlock the respective functionality.

According to an embodiment, the instrument is an oscilloscope. Oscilloscopes provide several functionalities that are typically not all known to a typical user. Therefore, the user gets an incentive to discover the several functionalities of the oscilloscope in an intuitive manner. In some embodiments, the user is motivated when reaching certain achievements.

In general, the instrument keeps track of any achievements of the user wherein the respective achievements relate to information how the user is handling the instrument.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows an instrument according to an embodiment of the present disclosure; and

FIG. 2 schematically shows a graphical user interface provided by the instrument of FIG. 1.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

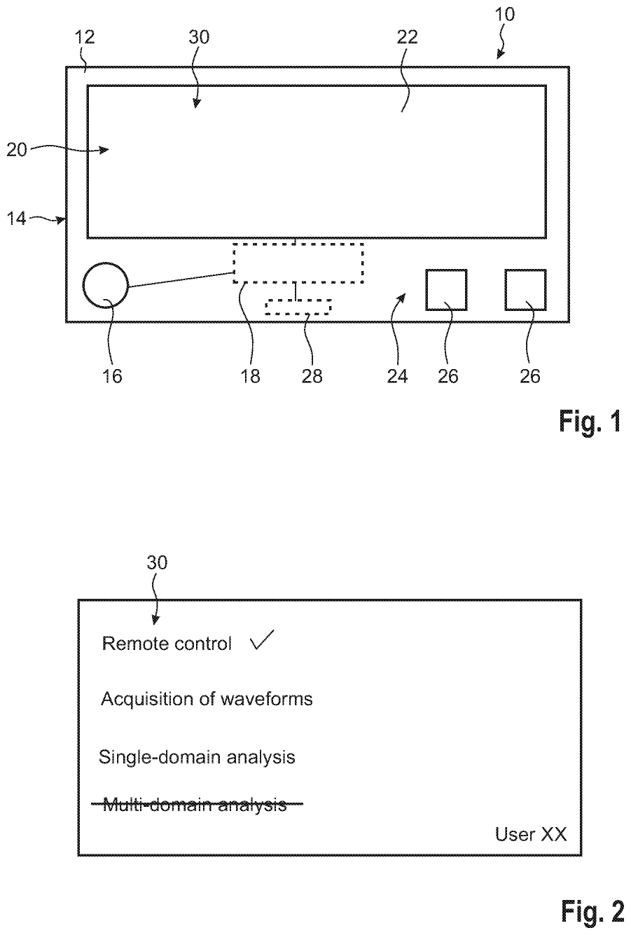

In FIG. 1, an instrument 10 for analyzing an input signal is shown that is established by an oscilloscope. The instrument 10 comprises an outer housing 12 that provides a front end 14. At the front end 14, an input 16 is provided for receiving an input signal that is processed internally by the instrument 10. The input 16 is internally connected with a processing circuit or module 18 for processing the input signal received, for example analyzing the input signal.

The processing module 18 is connected with a display, such as display module 20, for displaying information concerning the input signal analyzed. Hence, the processing module 18 forwards analysis results to be displayed to the display module 20 that displays the respective information. In the shown embodiment, the display module 20 comprises a touch-sensitive display 22 that is simultaneously part of a user input, such as input interface or module 24, of the instrument 10.

The user input module 24 comprises, besides the touch-sensitive display 22, other inputs such as buttons or knobs 26 that can be used by the user of the instrument 10 in order to enter instructions that are processed by the processing module 18 accordingly.

Generally, the user may set the instrument 10 by entering a respective setting via the user input module 24.

In addition, the instrument 10 comprises a data storage 28 that is connected with the processing module 18, which can access the data storage 28 in order to retrieve information. The respective information retrieved may concern to signal information of previously acquired signals or rather analyzed signals as well as user information, namely information concerning user accounts as will be described later in more detail. Hence, the instrument 10 can generally be used by different users wherein each user has its own user account.

In general, the processing module 18 together with the display module 20 is configured to generate a graphical user interface 30, abbreviated by GUI, that is illustrated by the display module 20, for example the touch-sensitive display 22, in order to inform the user of the instrument 10. A respective graphical user interface 30 is shown in FIG. 2 in more detail as will be described hereinafter.

As shown in FIG. 2, the instrument 10 provides several different functionalities like a remote control, an acquisition of a waveform, a single-domain analysis as well as a multi-domain analysis. The respective different functionalities correspond to different types.

In some embodiments, the different functionalities of the instrument 10 generally comprise functions of the instrument 10 like the remote control, operation modes of the instrument 10 like the acquisition of waveforms or the respective analysis and/or applications running on the instrument 10 like a web browser.

Each of the several functionalities is associated with the at least one respective complexity, wherein the respective complexity is associated with an intrinsic complexity that depends on the respective functionality. The different functionalities may have different intrinsic complexities. For instance, the multi-domain analysis probably has a higher complexity (level) compared to the single-domain analysis due to the number of domains involved in the respective analysis.

Furthermore, the respective complexity may also be associated with the duration and/or a number of results. For instance, the functionality “acquisition of waveforms” depends on the duration as well as the number of acquisitions or rather analysis results obtained. In some embodiments, it is more complex to acquire a certain number of waveforms in a shorter time period. In a similar manner, it is also more complex to acquire a higher number of waveforms in a fixed time period. Therefore, the respective complexity or rather the complexity level associated with the functionality “acquisition of waveforms” may also depend on the duration and/or the number of analysis results obtained.

The user may set the duration and/or the number of analysis results, namely the number of waveforms to be acquired, by using the user input module 24. The user may select the respective functionality of the instrument 10 via the touch-sensitive display 22, namely the functionality “acquisition of waveforms”. Then, the user is enabled to set the respective acquisition, namely the duration and/or the number of waveforms. Therefore, the user may use the knobs and/or buttons 26 or rather the touch-sensitive display 22 as well.

Furthermore, the type of input, namely the way how the instructions are done, also has an intrinsic complexity. In some embodiments, instructions made by voice, by using a button, by using a remote device or rather by using the touch-sensitive display 22 have different complexities. For instance, a zoom functionality may be done by using a pinching operation on the touch-sensitive display 22, by using a zoom button or rather by using a rotary button for zoom level adaption.

In any case, the instrument 10 is set by a respective setting of the user via the user input module 24, namely the instructions made by the user, to analyze the input signal received by using at least one of the several functionalities that is associated with a certain complexity.

The respective functionality may also correspond to the remote control that is used for analyzing the input signal such that the instrument 10 is controlled in a remote manner when analyzing the input signal.

The processing module 18 analyzes the input signal with respect to the setting of the user, thereby obtaining analysis results, for instance a certain number of waveforms in a certain time (in a remote manner), wherein the respective analysis results are associated with a single-domain analysis or rather a multi-domain analysis. This depends on the respective setting of the user done via the user input module 24, namely the instructions.

Besides the analysis of the input signal, the processing module 18 also evaluates the instructions or rather the setting of the user, for example with regard to the functionality and the complexity associated therewith.

This means that the processing module 18 investigates whether or not the instructions or rather the respective setting of the instrument 10 which was done by the user via the user input module 24 corresponds to a complex one or not.

In other words, the processing module 18 evaluates the complexity of the instructions of the user.

As mentioned above, the complexity of the instructions may be associated with the type of input done by the user, the intrinsic complexity of the respective functionality, a duration and/or a number of analysis results obtained.

Hence, the processing module 18 may evaluate the setting of the instrument 10 which was made by the instructions, wherein the respective setting is associated with at least one of the several functionalities of the instrument 10 and the respective complexity of the at least one of the several functionalities.

Furthermore, the processing module 18 also determines whether the user has reached a certain achievement based on the evaluation of the instructions, for example the functionality and the complexity associated therewith.

The processing module 18 may also evaluate the analysis results obtained together with the setting of the user with regard to the functionality and the complexity in order to determine the respective achievement of the user. For instance, the processing module 18 evaluates whether the analysis results are correct ones or not.

The respective achievement may be indicated on the graphical user interface 30 by a certain symbol as indicated in FIG. 2 by the check mark associated with the functionality remote control.

Hence, the user obtains an incentive to discover all functionalities of the instrument 10 as he becomes motivated to use the instrument 10 more intensively, thereby spending more time with the instrument 10 in order to get trained in a play-like manner.

Generally, the complexity determined is associated with a function of the instrument 10 and/or an application of the instrument 10. The different functionalities of the instrument 10 may relate to functions of the instrument 10, operation modes of the instrument 10 and/or applications running on the instrument 10 which can be used by the user to set the instrument 10 accordingly.

The processing module 18 takes the respective functionalities, for example their setting(s), into account in order to determine their corresponding complexity.

Accordingly, the instructions may relate to a respective setting of the instrument 10 according to which the input signal is to be analyzed. Hence, the instructions are also associated with at least one of the several functionalities of the instrument 10 and the respective complexity of the at least one of the several functionalities.

The respective functionalities as well as their complexities may further be used by the processing module 18 in order to determine an achievement of the user reached.

As mentioned above, the user gets motivated to discover all functionalities of the instrument 10. This incentive can be enhanced by illustrating via the graphical user interface 30 certain functionalities that have not been achieved by the user or rather that are currently locked, but can be unlocked in case of reaching a certain achievement, for example an achievement associated with a lower complexity level.

The user may unlock the respective functionality, for instance the multi-domain analysis, by reaching a certain achievement previously, for instance a successful single-domain analysis.

As illustrated in FIG. 2, the user has not yet performed a single-domain analysis since no check mark is illustrated. Hence, the multi-domain analysis which is more complex is still locked as illustrated by the crossing.

Since the locked functionality is illustrated, the user gets motivated to unlock the respective functionality. The functionality may be unlocked in a permanent manner or rather temporarily, thereby providing the user the possibility to use the unlocked functionality for a certain duration or rather a certain number of usages until the temporarily unlocked functionality is locked again.

The user however has the chance to investigate the unlocked functionality in order to figure out whether he wants to unlock the functionality permanently, for instance by paying a certain fee.

As discussed above, the instrument 10 may be used by different users, wherein the processing module 18 takes the activated user account into account when determining the individual achievement for the respective user that is logged in.

The respective achievement is associated with the user account rather than the entire instrument 10 that can be used by different users having more or less experience with the same instrument 10.

The current status of the user with regard to the achievements can also be stored in the data storage 28 that is accessed by the processing module 18 accordingly.

In general, the instrument 10 may determine and illustrate achievements of the user in order to offer an incentive to the user to discover more functionalities of the instrument 10, for example all available functionalities. This ensures that the user gets aware of these functionalities of the instrument 10.

The respective achievements can be provided by the instrument 10 in a certain manner such that a less experienced user gets trained with the instrument 10 in a pre-defined manner since the user has to reach the respective achievements in a pre-defined order, thereby following a pre-defined training sequence or rather routine.

The different achievements may be illustrated in a wizard-like manner in order to guide the user through the different functionalities of the instrument 10. Accordingly, the user is enabled to decide which kind of the several different functionalities are the most important ones.

Generally, the instrument 10 is enabled to evaluate the complexity of the instructions made by the user, which may relate to a respective setting of the instrument 10 for analyzing the input signal. Accordingly, the instructions the complexity thereof is evaluated are associated with at least one of the several functionalities of the instrument 10 and the respective complexity of this at least one functionality.

Certain embodiments disclosed herein utilize circuitry (e.g., one or more circuits) in order to implement protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph.

In an embodiment, circuitry includes, among other things, one or more computing devices such as a processor (e.g., a microprocessor), a central processing unit (CPU), a digital signal processor (DSP), an application-specific integrated circuit (ASIC), a field-programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

In some examples, the functionality described herein can be implemented by special purpose hardware-based computer systems or circuits, etc., or combinations of special purpose hardware and computer instructions.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. An instrument for analyzing an input signal, the instrument comprising an input for receiving an input signal, a processing circuit for analyzing the input signal received, a display for displaying information concerning the input signal analyzed, and a user input for receiving instructions from a user, the instrument providing several functionalities, the several functionalities each being associated with at least one respective complexity, the instrument being set by the instructions of the user via the user input to analyze the input signal, the processing circuit evaluating a complexity of the instructions of the user.

2. The instrument according to claim 1, wherein the processing circuit evaluates a complexity of a setting of the instrument, the setting being defined by the instructions of the user, the setting being associated with at least one of the several functionalities of the instrument.

3. The instrument according to claim 1, wherein the processing circuit determines an achievement of the user based on the evaluation of the complexity of the instructions.

4. The instrument according to claim 1, wherein the processing circuit analyzes the input signal with respect to the instructions of the user, thereby obtaining analysis results.

5. The instrument according to claim 4, wherein the processing circuit evaluates the analysis results obtained together with the complexity of the instructions of the user in order to determine an achievement of the user.

6. The instrument according to claim 1, wherein the several functionalities at least partly define how the input signal received via the input is to be analyzed by the instrument.

7. The instrument according to claim 1, wherein the complexity is associated with a function of the instrument.

8. The instrument according to claim 1, wherein the complexity is associated with an application of the instrument.

9. The instrument according to claim 1, wherein the several functionalities comprise functions of the instrument, operation modes of the instrument and/or applications running on the instrument.

10. The instrument according to claim 1, wherein the complexity is associated with a type of input done by the user, an intrinsic complexity of the respective functionality, a duration and/or a number of analysis results obtained.

11. The instrument according to claim 1, wherein the processing circuit controls the display to display the information concerning the input signal analyzed and/or an achievement determined.

12. The instrument according to claim 1, wherein the display has a touch-sensitive display which provides the user input at least partly.

13. The instrument according to claim 1, wherein the instrument provides different user accounts for using the instrument.

14. The instrument according to claim 13, wherein the processing circuit takes the respective user account activated into account when determining an achievement such that the achievement is based on the user account rather than the entire instrument.

15. The instrument according to claim 1, wherein a previously locked functionality of the instrument is unlocked when the processing circuit determines that a certain achievement has been reached that enables the user to use the previously locked functionality of the instrument.

16. The instrument according to claim 15, wherein the previously locked functionality of the instrument is unlocked for a pre-defined time or a pre-defined number of usages.

17. The instrument according to claim 15, wherein the processing circuit together with the display generates a graphical user interface that illustrates currently locked functionalities of the instrument which are enabled to be unlocked when reaching a respective achievement that enables the user to use the previously locked functionality of the instrument.

18. The instrument according to claim 1, wherein the instrument is an oscilloscope.
